(19) United States
(12) Patent Application Publication
(10) Pub. No.: US 2026/0334014 A1
(43) Pub. Date: Oct. 22, 2026

(54) DISPLAY PANEL AND ELECTRONIC DEVICE INCLUDING THE SAME

(71) Applicant: Samsung Display Co., Ltd., Yongin-si (KR)

(72) Inventors: Minyeul RYU, Yongin-si (KR); Daesoo KIM, Yongin-si (KR); Jun HEO, Yongin-si (KR)

(73) Assignee: Samsung Display Co., Ltd., Yongin-si (KR)

(21) Appl. No.: 19/529,296

(22) Filed: Feb. 4, 2026

(30) Foreign Application Priority Data
Apr. 15, 2025 (KR) 10-2025-0049082

(51) Int. Cl. H10K 59/122; H10K 59/127

(52) U.S. Cl. CPC H10K 59/122; H10K 59/127

(57) ABSTRACT

Provided is a display panel including a first substrate, a display element layer on the first substrate and including a first electrode, an emission layer on the first electrode, a second electrode on the emission layer, and a pixel-defining structure, a second substrate on the display element layer and opposing the first substrate, and a filler between the first substrate and the second substrate. The pixel-defining structure includes a pixel insulating layer including an opening corresponding to the first electrode, a first groove having a closed line shape, and a second groove having a closed line shape and surrounding the first groove in a plan view, a first spacer pattern partially overlapping the first groove and being on the pixel insulating layer, and a second spacer pattern partially overlapping the second groove, being closer to the first electrode than the first spacer pattern, and being on the pixel insulating layer.

### CROSS-REFERENCE TO RELATED APPLICATIONS

This U.S. non-provisional patent application claims priority under 35 U.S.C. § 119 of Korean Patent Application No. 10-2025-0049082, filed on Apr. 15, 2025, the entire contents of which are hereby incorporated by reference.

### BACKGROUND

Some example embodiments of the present disclosure relate to display panels and/or electronic devices including the same, and more particularly, to display panels including a filler and/or electronic devices including the same.

An electronic device, which provides an image for a user, such as a smartphone, a digital camera, a laptop computer, a navigation device, and a smart television includes a display panel for displaying an image. The display panel generates an image and provides the image to a user through a display screen. The display panel may be provided in a state in which an upper substrate and a lower substrate are bonded by a sealing material.

The display panel may include a filler disposed between the upper substrate and the lower substrate in order to improve light emission efficiency and/or mechanical strength. The filler may be introduced into a display element layer during a process of manufacturing the display panel and react with an emission layer, and thus a dark spot defect may occur.

### SUMMARY

Some example embodiments of the present disclosure provide display panels which reduces or prevents a dark spot defect and/or electronic devices including the same.

An example embodiment of the inventive concepts may provide a display panel including a first substrate, a display element layer on the first substrate and including a first electrode, an emission layer on the first electrode, a second electrode on the emission layer, and a pixel-defining structure, a second substrate on the display element layer and opposing the first substrate, and a filler between the first substrate and the second substrate. The pixel-defining structure may include a pixel insulating layer including an opening corresponding to the first electrode, a first groove having a closed line shape, and a second groove having a closed line shape and surrounding the first groove in a plan view, a first spacer pattern partially overlapping the first groove and being on the pixel insulating layer, and a second spacer pattern partially overlapping the second groove, being closer to the first electrode than the first spacer pattern, and being on the pixel insulating layer.

In an example embodiment, the second spacer pattern may include an inclined surface overlapping the second groove, the pixel insulating layer may include an inner side surface overlapping the inclined surface of the second spacer pattern and defining the second groove, and a first inclination angle of the inner side surface of the pixel insulating layer may be greater than a second inclination angle of the inclined surface of the second spacer pattern.

In an example embodiment, the first inclination angle of the inner side surface of the pixel insulating layer may be about 45 degrees to about 90 degrees, and the second inclination angle of the inclined surface of the second spacer pattern may be equal to or greater than about 15 degrees and smaller than about 45 degrees.

In an example embodiment, the pixel insulating layer may include a first inner side surface, a second inner side surface, and a lower surface between the first inner side surface and the second inner side surface, the first inner side surface, the second inner side surface, and the lower surface defining the first groove, the second inner side surface may be farther away from the first electrode than the first inner side surface, and the first spacer pattern may cover the second inner side surface of the first groove.

In an example embodiment, the pixel insulating layer may include a first inner side surface, a second inner side surface, and a lower surface between the first inner side surface and the second inner side surface, the first inner side surface, the second inner side surface, and the lower surface defining the second groove, the second inner side surface may be farther away from the first electrode than the first inner side surface, and the second spacer pattern may cover the first inner side surface of the second groove.

In an example embodiment, the pixel insulating layer may include a first portion overlapping the first spacer pattern, a second portion between the first groove and the second groove, and a third portion being a remaining portion other than the first portion and the second portion, and the second portion may not overlap the first spacer pattern and the second spacer pattern.

In an example embodiment, the opening may be defined in the third portion, and an edge of the third portion defining the opening may be spaced apart from the first electrode, and at least a portion of the second spacer pattern may overlap the first electrode.

In an example embodiment, the opening may be defined in the third portion, and an edge of the third portion defining the opening may overlap the first electrode.

In an example embodiment, the third portion may include an inclined surface overlapping the first electrode and an inner side surface defining the second groove, and a third inclination angle of the inclined surface of the third portion may be smaller than a fourth inclination angle of the inner side surface of the third portion.

In an example embodiment, the pixel insulating layer further includes may include a third groove having a closed line shape and being between the first groove and the second groove.

In an example embodiment, the third groove may not overlap the first spacer pattern and the second spacer pattern.

In an example embodiment, the pixel insulating layer may include a first portion overlapping the first spacer pattern, a second portion between the first groove and the second groove, and a third portion including the opening, the third portion overlapping the second spacer pattern and the first electrode, and an edge of the third portion defines the opening and may be exposed from the second spacer pattern.

In an example embodiment, a first height of the first spacer pattern may be greater than a second height of the second spacer pattern.

In an example embodiment, the second spacer pattern may have a closed line shape in a plan view, and the first spacer pattern may be on an inner side of the second spacer pattern in a plan view.

In an example embodiment, the display element layer may further include a capping layer on the second electrode, and the filler may be on the capping layer.

In an example embodiment of the inventive concepts, an electronic device may include a display panel, a processor configured to control the display panel, and a power module configured to supply power. The display panel includes a first substrate, a display element layer on the first substrate, the display element layer including a first electrode, an emission layer on the first electrode, a second electrode on the emission layer, and a pixel-defining structure, a second substrate on the display element layer and opposing the first substrate, and a filler between the first substrate and the second substrate. The pixel-defining structure includes a pixel insulating layer including an opening corresponding to the first electrode, a first groove having a closed line shape, and a second groove having a closed line shape and surrounding the first groove in a plan view, a first spacer pattern partially overlapping the first groove and being on the pixel insulating layer, and a second spacer pattern partially overlapping the second groove, being closer to the first electrode than the first spacer pattern, and being on the pixel insulating layer.

In an example embodiment, the second spacer pattern may include an inclined surface overlapping the second groove, the pixel insulating layer may include an inner side surface overlapping the inclined surface of the second spacer pattern and defining the second groove, and a first inclination angle of the inner side surface of the pixel insulating layer may be larger than a second inclination angle of the inclined surface of the second spacer pattern.

In an example embodiment, the first inclination angle of the inner side surface of the pixel insulating layer may be about 45 degrees to about 90 degrees, and the second inclination angle of the inclined surface of the second spacer pattern may be equal to or greater than about 15 degrees and smaller than about 45 degrees.

In an example embodiment, the pixel insulating layer may include a first inner side surface, a second inner side surface, and a lower surface between the first inner side surface and the second inner side surface, the first inner side surface, the second inner side surface, and the lower surface defining the first groove, the second inner side surface may be farther away from the first electrode than the first inner side surface, and the first spacer pattern may cover the second inner side surface of the first groove.

In an example embodiment, the pixel insulating layer may include a first portion overlapping the first spacer pattern, a second portion between the first groove and the second groove, and a third portion being a remaining portion other than the first portion and the second portion, and the second portion may not overlap the first spacer pattern and the second spacer pattern.

### BRIEF DESCRIPTION OF THE FIGURES

The accompanying drawings are included to provide a further understanding of the inventive concepts, and are incorporated in and constitute a part of this specification. The drawings illustrate some example embodiments of the inventive concepts and, together with the description, serve to explain some principles of the inventive concepts. In the drawings:

FIG. 1 is a block diagram of an electronic device according to an example embodiment of the inventive concepts;

FIG. 2 is a schematic view of electronic devices according to various example embodiments;

FIG. 3 is an assembled perspective view of an electronic device according to an example embodiment of the inventive concepts;

FIG. 4 is an exploded perspective view of an electronic device according to an example embodiment of the inventive concepts;

FIG. 5 is a cross-sectional view of a display device according to an example embodiment of the inventive concepts;

FIG. 6 is a cross-sectional view of an active region of a display panel according to an example embodiment of the inventive concepts;

FIG. 7 is a plan view of a display panel according to an example embodiment the inventive concepts;

FIG. 8A is an enlarged plan view of a portion of a display panel according to an embodiment of the inventive concepts;

FIG. 8B is a cross-sectional view of a display panel according to an example embodiment of the inventive concepts; and

FIGS. 9A to 9C are cross-sectional views of display panels according to some example embodiment of the inventive concepts.

### DETAILED DESCRIPTION

In this specification, it will be understood that when an element (or a region, a layer, a portion, or the like) is referred to as being “on”, “connected to” or “coupled to” another element, it may be directly disposed on, connected to, or coupled to the other element, or other elements may be disposed therebetween.

Like reference numerals or symbols refer to like elements throughout. In the drawings, the thickness, ratio, and size of the elements are exaggerated for effectively describing the technical contents. As used herein, the term “and/or” includes any and all combinations of one or more of the associated listed elements.

It will be understood that, although the terms “first”, “second”, etc. may be used herein to describe various elements, the elements are not to be limited by these terms. These terms are only used to distinguish one element, component, region, layer or section from another element, component, region, layer or section. For instance, a first element, component, region, layer or section discussed below could be termed a second element, component, region, layer or section without departing from the scope of the inventive concepts. Similarly, a second element, component, region, layer or section could be termed a first element, component, region, layer or section. In this specification, the singular expressions “a”, “an” and “the” are intended to include the plural forms as well, unless the context clearly indicates otherwise.

In addition, the terms “below”, “under”, “on the lower side”, “above”, “over”, “on the upper side”, or the like may be used to describe the relationships between the elements illustrated in the drawings. These terms are relative concepts and are described on the basis of the directions indicated in the drawings.

It will be further understood that the terms “comprises, includes, has” and/or “comprising, including, having”, when used in this specification, specify the presence of stated features, numbers, steps, operations, elements, components or combinations thereof, but do not preclude the possibility of the presence or addition of one or more other features, numbers, steps, operations, elements, components, and/or combinations thereof.

As used herein, expressions such as “one of,” “one or more of,” “any one of,” “least one of,” “at least one among,” and “at least one selected from” when preceding a list of elements, modify the entire list of elements and do not modify the individual elements of the list. Thus, for example, both “at least one of A, B, or C” and “at least one of A, B, and C” mean either A, B, C or any combination thereof. Likewise, A and/or B means A, B, or A and B.

While the term “same,” “equal” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., ±10%).

When the term “about,” “substantially” or “approximately” is used in this specification in connection with a numerical value, it is intended that the associated numerical value includes a manufacturing or operational tolerance (e.g., ±10%) around the stated numerical value. Moreover, when the word “about,” “substantially” or “approximately” is used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, some example embodiments of the inventive concepts are described with reference to the drawings.

A display device according to an example embodiment may be applied to various electronic devices. An electronic device according to an example embodiment may include the display device described above and may further include another module or device having an additional function in addition to the display device.

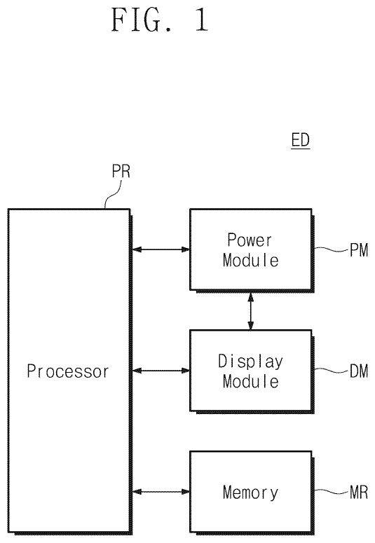

FIG. 1 is a block diagram of an electronic device ED according to an example embodiment of the inventive concepts. Referring to FIG. 1, the electronic device ED according to an example embodiment may include a display module DM, a processor PR, a memory MR, and a power module (or alternatively referred to as a power supply or power supply circuitry) PM.

The processor PR may include at least one among a central processing unit (CPU), an application processor (AP), a graphic processing unit (GPU), a communication processor (CP), an image signal processor (ISP), or a controller.

Data information desired for an operation of the processor PR or the display module DM may be stored in the memory MR. When the processor PR executes an application stored in the memory MR, an image data signal and/or an input control signal may be transferred to the display module DM, and the display module DM may process the provided signal and output image information through a display screen.

The power module PM may include, for example, a power supply module such as a power adapter or a battery device and a power conversion module configured to convert power supplied by the power supply module and generate power desired for an operation of the electronic device ED.

At least one of the components of the electronic device ED described above may be included in a display device according to the example embodiments described above. In addition, some of individual modules included in functionally one module may be included in the display device, and the others thereof may be provided separately from the display device. For example, the display device may include the display module DM, and the processor PR, the memory MR, and the power module PM may be provided in a form of another device in the electronic device ED, not in the display device.

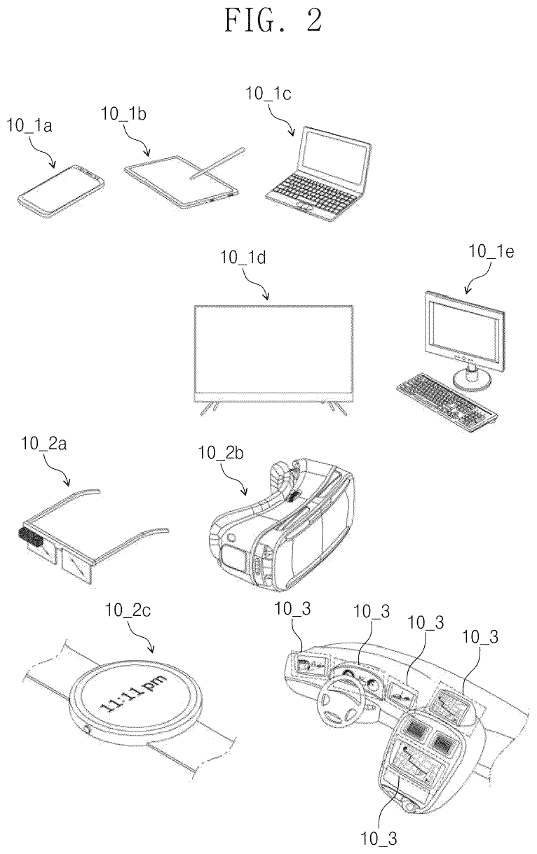

Referring to FIG. 2, various electronic devices to which a display device according to example embodiments is applied may include not only an electronic device for displaying images, such as a smartphone 10_1a, a tablet PC 10_1b, a laptop computer 10_1c, a television 10_1d, and a desk monitor 10_1e but also a wearable electronic device including a display module, such as smart glasses 10_2a, a head-mounted display 10_2b, and a smart watch 10_2c, an automotive electronic device 10_3 including a display module, such as a center information display (CID) disposed on an instrument panel, center fascia, and a dashboard of an automobile and a room mirror display, etc.

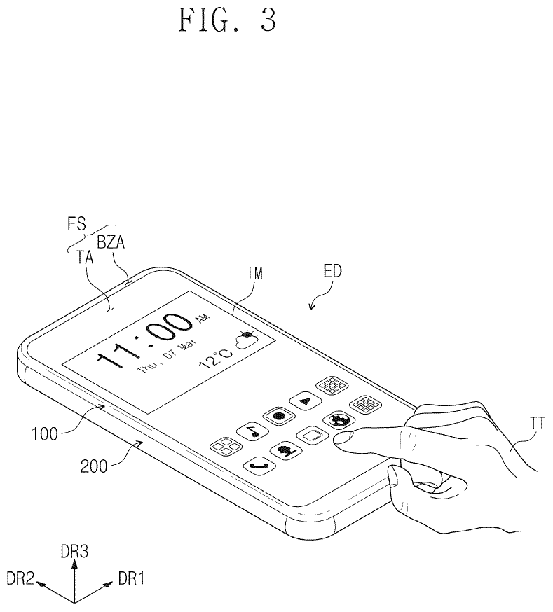

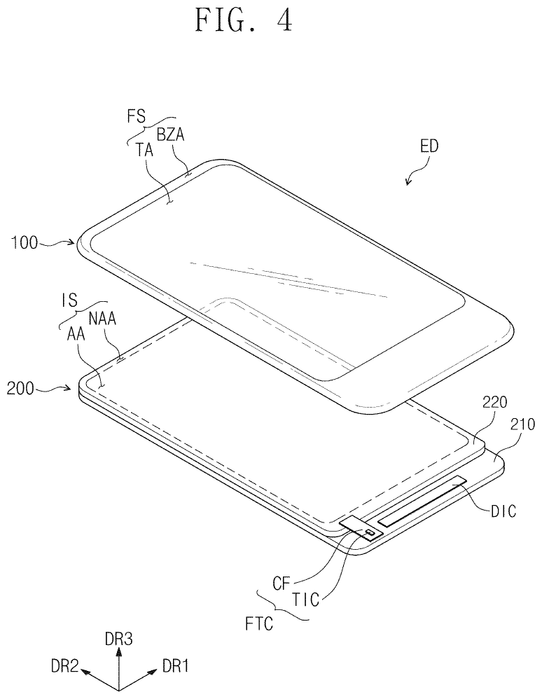

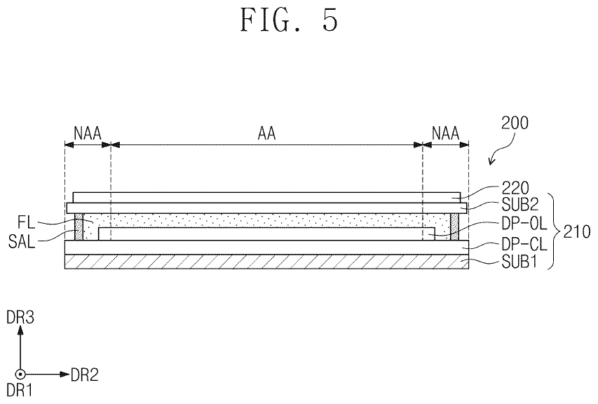

FIG. 3 is an assembled perspective view of an electronic device ED according to an example embodiment of the inventive concepts. FIG. 4 is an exploded perspective view of an electronic device ED according to an example embodiment of the inventive concepts. FIG. 5 is a cross-sectional view of a display device according to an example embodiment of the inventive concepts.

Referring to FIGS. 3 and 4, the electronic device ED may be a device activated in response to an electrical signal. In an example embodiment of the inventive concepts, the electronic device ED is illustrated as a smartphone as an example.

The electronic device ED may display an image IM through a display surface FS. The display surface FS is parallel to a plane defined by a first direction DR1 and a second direction DR2. A normal direction of the display surface FS, that is, a thickness direction of the electronic device ED is indicated by a third direction DR3. A front surface (or an upper surface) and a rear surface (or a lower surface) of each of members or units described below are divided by the third direction DR3.

The display surface FS on which the image IM is displayed may correspond to a front surface of the electronic device ED, and the display surface FS of the electronic device ED may substantially correspond to a front surface of a window member (or alternatively, a window) 100. Hereinafter, the display surface and the front surface of the electronic device ED and the front surface FS of the window member 100 will be denoted as the same reference numerals or symbols. A clock and a plurality of icons are illustrated in FIG. 3 as an example of the image IM.

The electronic device ED includes the window member 100 and a display device 200. Although not separately illustrated, the electronic device ED may further include an optical member disposed between the window member 100 and the display device 200. The optical member may include a polarizer. The optical member may include a color filter member (or alternatively, a color filter) for lowering external light reflectance.

The window member 100 includes a base panel. For example, the base panel may include glass, plastic, or a combination thereof. The front surface FS of the window member 100 includes a transmission region TA and a bezel region BZA. The transmission region TA may be an optically transparent region. For example, the transmission region TA may be a region having a visible light transmittance of about 90 % or more.

The bezel region BZA may be a region having relatively low light transmittance compared to the transmission region TA. The bezel region BZA defines a shape of the transmission region TA. The bezel region BZA may be adjacent to the transmission region TA and surround the transmission region TA. The window member 100 may further include a colored light-blocking pattern which is disposed on the base panel and defines the bezel region BZA.

The bezel region BZA may have a color. The bezel region BZA may cover a peripheral region NAA of the display device 200 and block the peripheral region NAA from being viewed from the outside. This is illustrated as an example, and the bezel region BZA may be omitted from the window member 100 according to an example embodiment of the inventive concepts.

The display device 200 may display the image IM and sense an external input TT. The image IM may be displayed on a front surface IS of the display device 200. The front surface IS of the display device 200 includes an active region AA and the peripheral region NAA. The active region AA may be a region activated in response to an electrical signal.

In an example embodiment of the inventive concepts, the active region AA may be a region in which the image IM is displayed and a region in which the external input TT is sensed at the same time. The active region AA corresponds to the transmission region TA, and the peripheral region NAA corresponds to the bezel region BZA. In this specification, the wording “a region/portion corresponds to a region/portion” means that “a region/portion and a region/portion overlap each other” and is not limited to a case in which regions/portions have the same area and/or the same shape.

The display device 200 includes a display panel 210, a sensing panel 220, a driving circuit DIC, and a circuit module FTC.

The display panel 210 may generate the image IM. The display panel 210 may be an organic light-emitting display panel or a quantum dot light-emitting display panel. The panels are distinguished from each other according to a material of a light-emitting element. An emission layer of the organic light-emitting display panel may include an organic light-emitting material. An emission layer of the quantum dot light-emitting display panel may include quantum dots, quantum rods, and/or the like. Hereinafter, the display panel 210 is described as an organic light-emitting display panel.

The sensing panel 220 senses an external input (e.g., a touch event) applied from the outside. In an example embodiment of the inventive concepts, the sensing panel 220 may be a capacitive type and is not particularly limited.

The driving circuit DIC is disposed on the display panel 210. The driving circuit DIC may be mounted on the display panel 210. The driving circuit DIC is electrically connected to the display panel 210 and provides, to the display panel 210, an electrical signal for driving the display panel 210.

The circuit module FTC is electrically connected to the sensing panel 220. In an example embodiment of the inventive concepts, the circuit module FTC may include a flexible circuit board CF and a sensing driving circuit TIC. The flexible circuit board CF includes lines that are not illustrated. The lines electrically connect the sensing panel 220 and the sensing driving circuit TIC. The sensing driving circuit TIC may be mounted and provided on the flexible circuit board CF in a chip-on-film form.

The circuit module FTC may connect the sensing panel 220 and the display panel 210. The sensing driving circuit TIC may be omitted. In some example embodiments, the sensing driving circuit TIC and the driving circuit DIC may be integrated into one circuit.

Referring to FIG. 5, a display panel 210 may include a first substrate SUB1, a circuit element layer DP-CL, a display element layer DP-OL, a second substrate SUB2, a sealing material SAL, and a filler FL. A sensing panel 220 may be disposed on the second substrate SUB2.

The first substrate SUB1 may include an active region AA and a peripheral region NAA adjacent to the active region AA. The display element layer DP-OL may overlap the active region AA. In an example embodiment of the inventive concepts, the first substrate SUB1 may be a rigid type. For example, the first substrate SUB1 may include a glass substrate, a metal substrate, a polymer substrate, or an organic/inorganic composite material substrate.

The circuit element layer DP-CL is disposed on the first substrate SUB1. The circuit element layer DP-CL includes at least one insulating layer and a circuit element. The insulating layer includes at least one inorganic film and at least one organic film. The circuit element includes a signal line, a pixel driving circuit, etc. The circuit element layer DP-CL may be formed through a process of forming an insulating layer, a semiconductor layer, and a conductive layer by coating, deposition, or the like and a process of patterning the insulating layer, the semiconductor layer, and the conductive layer by a photolithography process.

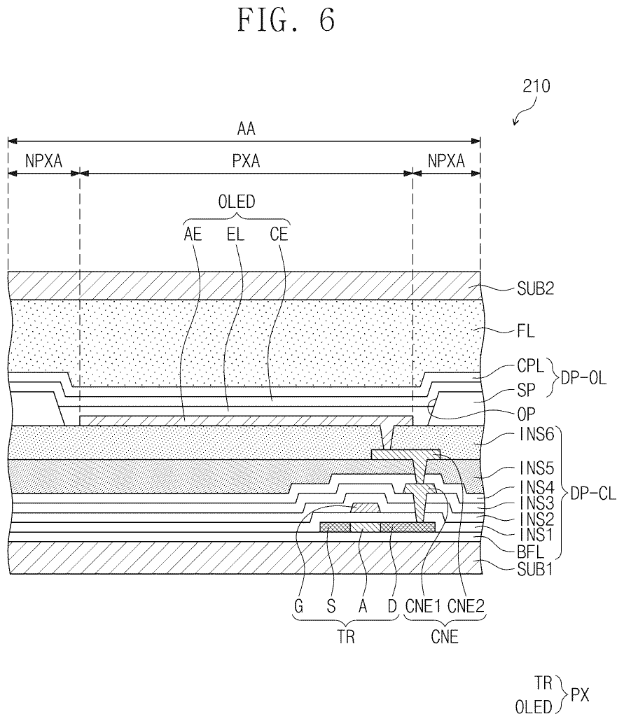

The display element layer DP-OL is disposed on the circuit element layer DP-CL. A stack structure of the display element layer DP-OL is described in detail with reference to FIG. 6.

The sealing material SAL is disposed between the second substrate SUB2 and the first substrate SUB1. The sealing material SAL may be disposed on the circuit element layer DP-CL and overlap the peripheral region NAA. The sealing material SAL may have a closed loop shape surrounding the active region AA in a plan view. The first substrate SUB1 and the second substrate SUB2 may be bonded by using the sealing material SAL. The sealing material SAL may include a thermosetting material or a photocurable material. However, a material of the sealing material SAL is not limited to the above example.

The filler FL may fill an inner space defined by the first substrate SUB1, the second substrate SUB2, and the sealing material SAL. The filler FL may include a silicon-based, epoxy-based, or acrylic thermosetting material.

After the circuit element layer DP-CL and the display element layer DP-OL are formed on the first substrate SUB1, a process of bonding the filler FL and the sealing material SAL attached to the second substrate SUB2 to the first substrate SUB1 may be performed. In this case, the sealing material SAL may be cured by irradiating the sealing material SAL with a laser beam. During curing of the sealing material SAL, the filler FL may fill the inner space while being moved in a direction from the active region AA to the peripheral region NAA between the display element layer DP-OL and the second substrate SUB2.

FIG. 6 is a cross-sectional view of an active region AA of a display panel 210 according to an example embodiment of the inventive concepts.

A pixel PX according to an example embodiment of the inventive concepts may be defined as including a transistor TR and a light-emitting element OLED.

The transistor TR and the light-emitting element OLED may be disposed on a first substrate SUB1. One transistor TR is illustrated as an example, but the pixel PX may include a plurality of transistors and at least one capacitor for driving the light-emitting element OLED.

A buffer layer BFL may be disposed on the first substrate SUB1, and the buffer layer BFL may be an inorganic layer. A semiconductor pattern may be disposed on the buffer layer BFL. The semiconductor pattern may include polysilicon, amorphous silicon, or metal oxide.

The semiconductor pattern may be doped with an N-type dopant or a P-type dopant. The semiconductor pattern may include a relatively heavily doped region and a relatively lightly doped region. Conductivity of the relatively heavily doped region may be higher than the relatively lightly doped region. The semiconductor pattern may serve as a source electrode and a drain electrode of the transistor TR. The relatively lightly doped region may correspond to an active (or a channel) of the transistor.

A source S, an active A, and a drain D of the transistor TR may be formed from the semiconductor pattern. A first insulating layer INS1 may be disposed on the semiconductor pattern. A gate G of the transistor TR may be disposed on the first insulating layer INS1. A second insulating layer INS2 may be disposed on the gate G. A third insulating layer INS3 may be disposed on the second insulating layer INS2.

A connection electrode CNE may include a first connection electrode CNE1 and a second connection electrode CNE2 for connecting the transistor TR and the light-emitting element OLED. However, either the first connection electrode CNE1 or the second connection electrode CNE2 may be omitted. The first connection electrode CNE1 may be disposed on the third insulating layer INS3 and connected to the drain D through a first contact hole defined in the first to third insulating layers INS1, INS2, and INS3.

A fourth insulating layer INS4 may be disposed on the first connection electrode CNE1. A fifth insulating layer INS5 may be disposed on the fourth insulating layer INS4. The second connection electrode CNE2 may be disposed on the fifth insulating layer INS5. The second connection electrode CNE2 may be connected to the first connection electrode CNE1 through a second contact hole defined in the fourth and fifth insulating layers INS4 and INS5.

A sixth insulating layer INS6 may be disposed on the second connection electrode CNE2. The layers from the buffer layer BFL up to the sixth insulating layer INS6 may be defined as a circuit element layer DP-CL. The first insulating layer to the sixth insulating layer INS1 to INS6 may each be an inorganic layer or an organic layer.

A display element layer DP-OL may include the light-emitting element OLED and a pixel-defining structure PDL.

The light-emitting element OLED may include a first electrode AE, an emission layer EL, and a second electrode CE. The light-emitting element OLED according to an example embodiment may further include a hole control layer disposed between the first electrode AE and the emission layer EL and an electron control layer disposed between the emission layer EL and the second electrode CE.

The first electrode AE may be disposed on the sixth insulating layer INS6. The first electrode AE may be connected to the second connection electrode CNE2 through a third contact hole defined in the sixth insulating layer INS6. A pixel insulating layer SP having defined therein an opening OP corresponding to the first electrode AE may be disposed on the first electrode AE and the sixth insulating layer INS6. The pixel insulating layer SP is spaced apart from the first electrode AE but example embodiments of the inventive concepts are not limited thereto. For example, the pixel insulating layer SP may cover an edge of the first electrode AE.

In an example embodiment of the inventive concepts, the active region AA may include a light-emitting region PXA corresponding to each of pixels and a non-light-emitting region NPXA around the light-emitting region PXA. The light-emitting region PXA may correspond to an area of the first electrode AE that is exposed, and the non-light-emitting region NPXA may correspond to a region not overlapping the first electrode AE. The light-emitting region PXA may be different from a region exposed by the opening OP but is not necessarily limited thereto. For example, the light-emitting region PXA may correspond to an area of the first electrode AE exposed by the opening OP.

The emission layer EL may be disposed on the first electrode AE. The emission layer EL may be disposed in a region corresponding to the opening OP, and the emission layer EL may include an organic material and/or an inorganic material. The emission layer EL may generate light of any one of red, green, or blue.

The second electrode CE may be disposed on the emission layer EL. The second electrode CE may be disposed in the pixels in common. Thus, the second electrode CE may be disposed all over the light-emitting region PXA and the non-light-emitting region NPXA. In an example embodiment of the inventive concepts, a layer in which the light-emitting element OLED is disposed may be defined as the display element layer DP-OL.

A first voltage may be applied to the first electrode AE through the transistor TR, and a second voltage may be applied to the second electrode CE. Holes and electrons injected to the emission layer EL may combine to form excitons, and as the excitons transition to a ground state, the light-emitting element OLED may emit light.

The display element layer DP-OL according to an example embodiment of the inventive concepts may further include an upper organic layer CPL. The upper organic layer CPL may cover the second electrode CE and may be disposed all over the light-emitting region PXA and the non-light-emitting region NPXA like the second electrode CE. The upper organic layer CPL may include an organic material and have a thickness greater than a thickness of the second electrode CE. In this specification, the upper organic layer CPL may be referred to as a capping layer.

A filler FL may be disposed on the display element layer DP-OL and cover the pixel. The filler FL may be in contact with the upper organic layer CPL and a rear surface of a second substrate SUB2. In this specification, “a rear surface of a second substrate SUB2” may be defined as a surface, which faces the display element layer DP-OL, of the second substrate SUB2. The second substrate SUB2 may be disposed on the filler FL.

The second substrate SUB2 is disposed opposing the first substrate SUB1 and covers the display element layer DP-OL. The second substrate SUB2 according to an example embodiment may be an encapsulation substrate. The second substrate SUB2 may include a glass substrate, a metal substrate, a polymer substrate, or an organic/inorganic composite material substrate.

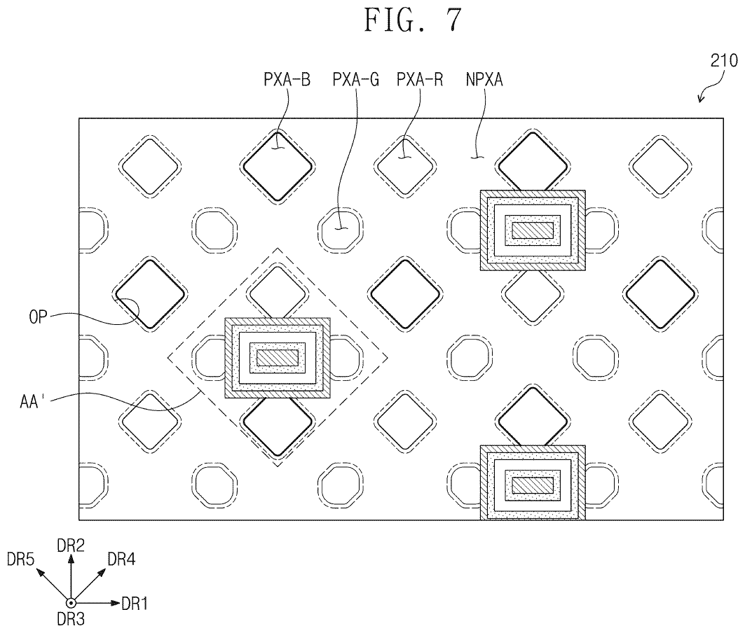

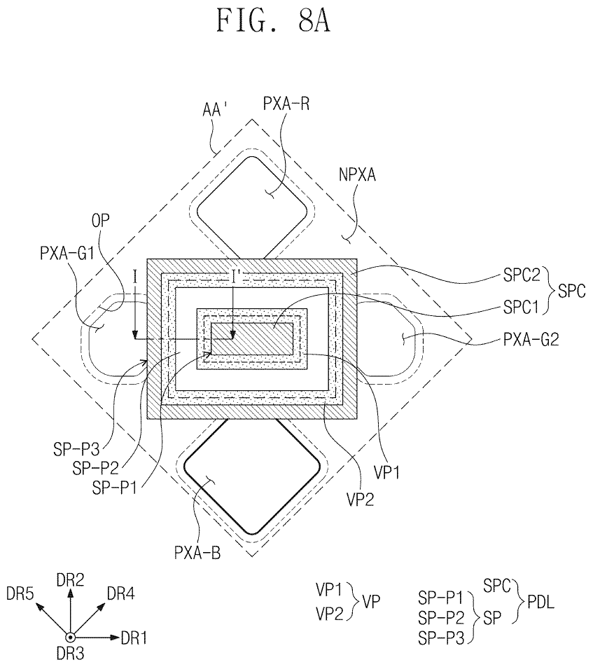

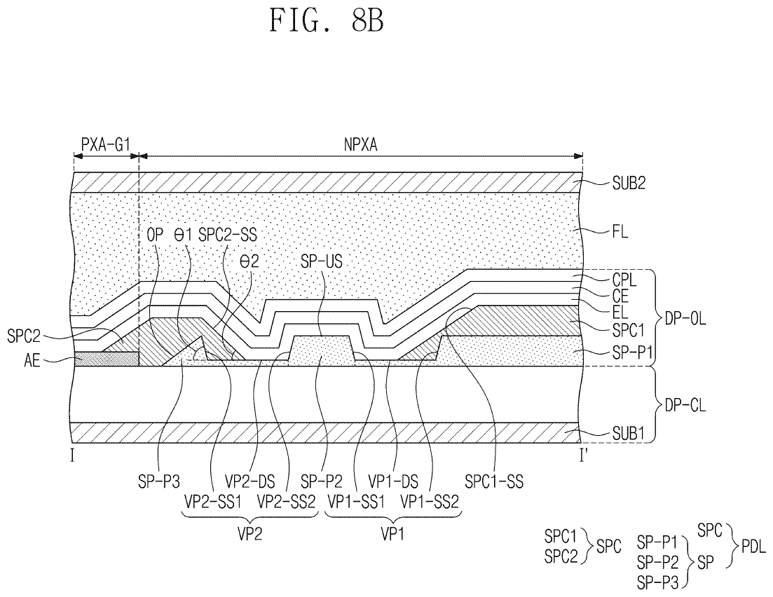

FIG. 7 is a plan view of a display panel according to an example embodiment the inventive concepts. FIG. 8A is an enlarged plan view of a portion of a display panel according to an example embodiment of the inventive concepts. FIG. 8B is a cross-sectional view of a display panel according to an example embodiment of the inventive concepts. FIG. 8A illustrates, in an enlarged view, a region AA′ illustrated in FIG. 7, and FIG. 8B is a cross-sectional view, which corresponds to I-I′ illustrated in FIG. 8A, of a display panel.

A display panel 210 may include a plurality of light-emitting regions PXA-R, PXA-G, and PXA-B and a non-light-emitting region NPXA surrounding the plurality of light-emitting regions PXA-R, PXA-G, and PXA-B. The plurality of light-emitting regions PXA-R, PXA-G, and PXA-B may include a first light-emitting region PXA-R, a second light-emitting region PXA-G, and a third light-emitting region PXA-B. The first light-emitting region PXA-R, the second light-emitting region PXA-G, and the third light-emitting region PXA-B may display light of wavelengths different from each other, respectively. The first light-emitting region PXA-R may display first light which is light of red wavelength, the second light-emitting region PXA-G may display second light which is light of green wavelength, and the third light-emitting region PXA-B may display third light which is light of blue wavelength.

Each of the plurality of light-emitting regions PXA-R, PXA-G, and PXA-B may be a region corresponding to the exposed first electrode AE (see FIG. 6). The non-light-emitting region NPXA may be regions between neighboring light-emitting regions PXA-R, PXA-G, and PXA-B, which is a region overlapping a pixel insulating layer SP. The plurality of light-emitting regions PXA-R, PXA-G, and PXA-B in this specification may each correspond to a “pixel”. The plurality of light-emitting regions PXA-R, PXA-G, and PXA-B may each correspond to an opening OP defined in the pixel insulating layer SP. The opening OP may partially overlap the non-light-emitting region NPXA.

The first light-emitting region PXA-R and the third light-emitting region PXA-B may be alternately arranged along the first direction DR1, thus constituting a first pixel group, and the second light-emitting region PXA-G may be arranged along the first direction DR1, thus constituting a second pixel group.

The first pixel group including the first light-emitting region PXA-R and the third light-emitting region PXA-B and the second pixel group including the second light-emitting region PXA-G may be spaced apart along the second direction DR2. The first pixel group and the second pixel group may be alternately arranged along the second direction DR2. In a plan view, the third light-emitting region PXA-B, which emits the third light, may have the largest area, and the second light-emitting region PXA-G, which generates the second light, may have the smallest area. In a unit area, the second light-emitting region PXA-G may be disposed twice as many as each of the first light-emitting region PXA-R and the third light-emitting region PXA-B.

The plurality of light-emitting regions PXA-R, PXA-G, and PXA-B may each have a polygonal shape having a rounded corner in a plan view. In an example embodiment, the first light-emitting region PXA-R and the third light-emitting region PXA-B may each have a square shape having sides of the same length, which extend in a fourth direction DR4 and a fifth direction DR5, respectively, and have rounded corners. The second light-emitting region PXA-G may have a shape having sides extending in either the fourth direction DR4 or the fifth direction DR5 and the remaining portion being rounded.

FIG. 8A illustrates, in an enlarged view, the region AA′ illustrated in FIG. 7. I FIG. 8A, two second light-emitting regions PXA-G adjacent to each other in the first direction DR1 may be defined as a (2-1)-th light-emitting region PXA-G1 and a (2-2)-th light-emitting region PXA-G2, respectively. A pixel-defining structure PDL includes a pixel insulating layer SP and a spacer SPC. An opening OP corresponding to the first electrode AE (see FIG. 6) and a groove VP recessed along a thickness direction are defined in the pixel insulating layer SP. The groove VP are provided in plurality, and the plurality of grooves VP include a first groove VP1 and a second groove VP2.

In a plan view, the first groove VP1 may have a closed line shape, and the second groove VP2 may have a closed line shape surrounding the first groove VP1. The first groove VP1 may be disposed farther away from each of the light-emitting regions PXA-R, PXA-G1, PXA-G2, and PXA-B than the second groove VP2.

The spacer SPC is disposed on the pixel insulating layer SP and includes a first spacer pattern SPC1 and a second spacer pattern SPC2. A portion of the first spacer pattern SPC1 may overlap the first groove VP1, and a portion of the second spacer pattern SPC2 may overlap the second groove VP2. The second spacer pattern SPC2 may be positioned closer to the first electrode AE (see FIG. 6) than the first spacer pattern SPC1 and may be spaced apart from the first spacer pattern SPC1. The second spacer pattern SPC2 may have a closed line shape in a plan view, and the first spacer pattern SPC1 may be disposed on an inner side of the second spacer pattern SPC2 in a plan view. The second spacer pattern SPC2 may partially overlap the light-emitting regions PXA-R, PXA-G1, PXA-G2, and PXA-B.

During a process of manufacturing the display panel, a deposition mask, which is used to distinguish the plurality of light-emitting regions PXA-R, PXA-G1, PXA-G2, and PXA-B from each other, may touch an upper surface of the spacer SPC. For example, a fine metal mask (FMM) may be used as the deposition mask. When the FMM mask is in excessive contact with the upper surface of the spacer SPC, a crack phenomenon may occur at the upper surface of the spacer SPC. Due to the crack phenomenon, a filler FL may be partially introduced into an emission layer EL and react with an organic material of the emission layer EL in a light-emitting region PXA. Accordingly, a dark spot defect or a dot stain may appear. According to some example embodiments of the inventive concepts, the grooves VP1 and VP2 defined in the non-light-emitting region NPXA may be included in the pixel insulating layer SP, and thus the filler FL introduced due to the crack phenomenon may be reduced or prevented from being introduced into the light-emitting region PXA.

Referring to FIGS. 8A and 8B together, a height of the first spacer pattern SPC1 (e.g., a distance between an upper surface of the first spacer pattern SPC1 and the substrate SUB1) may be greater than a height of the second spacer pattern SPC2 (e.g., a distance between an upper surface of the second spacer pattern SPC2 and the substrate SUB1). Accordingly, the FMM mask may be in contact with an upper surface of the first spacer pattern SPC1 first. Thus, even if a crack is formed at the upper surface of the first spacer pattern SPC1, the filler FL may be reduced or prevented from being introduced into the light-emitting region PXA-G because the first spacer pattern SPC1 is positioned farther away from the first electrode AE.

The pixel insulating layer SP may include a first inner side surface VP1-SS1, a second inner side surface VP1-SS2, and a lower surface VP1-DS between the first inner side surface VP1-SS1 and the second inner side surface VP1-SS2 that define the first groove VP1. In other words, the pixel insulating layer SP may define the first groove VP1 having a first inner side surface VP1-SS1, a second inner side surface VP1-SS2, and a lower surface VP1-DS between the first inner side surface VP1-SS1 and the second inner side surface VP1-SS2. Referring to FIG. 8B, the second inner side surface VP1-SS2 of the first groove VP1 is disposed farther away from the first electrode AE than the first inner side surface VP1-SS1 of the first groove VP1. The first spacer pattern SPC1 may cover the second inner side surface VP1-SS2 of the first groove VP1.

The pixel insulating layer SP may include a first inner side surface VP2-SS1, a second inner side surface VP2-SS2, and a lower surface VP2-DS between the first inner side surface VP2-SS1 and the second inner side surface VP2-SS2 that define the second groove VP2. In other words, the pixel insulating layer SP may define a second groove VP2 having a first inner side surface VP2-SS1, a second inner side surface VP2-SS2, and a lower surface VP2-DS between the first inner side surface VP2-SS1 and the second inner side surface VP2-SS2Referring to FIG. 8B, the second inner side surface VP2-SS2 of the second groove VP2 is disposed farther away from the first electrode AE than the first inner side surface VP2-SS1 of the second groove VP2. The second spacer pattern SPC2 may cover the first inner side surface VP2-SS1 of the second groove VP2.

According to an example embodiment, the second spacer pattern SPC2 may include an inclined surface SPC2-SS at least partially overlapping the second groove VP2. The pixel insulating layer SP may include the inner side surface VP2-SS1, which overlaps the inclined surface SPC2-SS of the second spacer pattern SPC2 and defines the second groove VP2.

An inclination angle θ1 of the inner side surface VP2-SS1 of the pixel insulating layer SP may be greater than an inclination angle θ2 of the inclined surface SPC2-SS of the second spacer pattern SPC2. Accordingly, even if a crack is formed at the second spacer SPC2, the crack may be formed at a gentler angle, and thus the filler FL may be reduced or prevented from being introduced into the inner side surface VP2-SS1 of the second groove VP2. Because introduction of the filler FL into an inner side of the second groove VP2 is suppressed, occurrence of a dark spot defect in the emission layer EL of the light-emitting region PXA-G may be reduced or prevented.

According to an example embodiment, the inclination angle θ1 of the first inner side surface VP2-SS1 of the second groove VP2 of the pixel insulating layer SP may be about 45 degrees to about 90 degrees, and the inclination angle θ2 of the inclined surface SPC2-SS of the second spacer pattern SPC2 may be equal to or greater than about 15 degrees and smaller than about 45 degrees. An inclination angle of the closest side surface of the pixel insulating layer SP to the light-emitting region PXA-G may be smaller than the inclination angle θ1 of the inner side surface VP2-SS1 of the second groove VP2.

Referring to FIGS. 8A and 8B together, the pixel insulating layer SP may include a first portion SP-P1 which overlaps the first spacer pattern SPC1, a second portion SP-P2 which is positioned between the first groove VP1 and the second groove VP2, and a third portion SP-P3 which is a remaining portion other than the first portion SP-P1 and the second portion SP-P2. The second portion SP-P2 may not overlap the first spacer pattern SPC1 and the second spacer pattern SPC2. That is, the spacer SPC may not be disposed on an upper surface SP-US of the second portion SP-P2. The first spacer pattern SPC1 and the second spacer pattern SPC2 may be spaced apart with respect to the second portion SP-P2. In other words, the first spacer pattern SPC1 and the second spacer pattern SPC2 may be spaced apart with the second portion SP-P2 therebetween.

Referring to FIGS. 8A and 8B together, the opening OP may be defined in the third portion SP-P3 of the pixel insulating layer SP, and an edge of the third portion SP-P3 defining the opening OP may be spaced apart from the first electrode AE. The second spacer pattern SPC2 may overlap the first electrode AE and overlap a portion of the third portion SP-P3. Because the second spacer pattern SPC2 is disposed, an effective or actual area of the light-emitting region PXA-G may be decreased. A portion of the light-emitting regions PXA-R, PXA-G1, PXA-G2, and PXA-B adjacent to the spacer SPC may be covered by the second spacer SPC2.

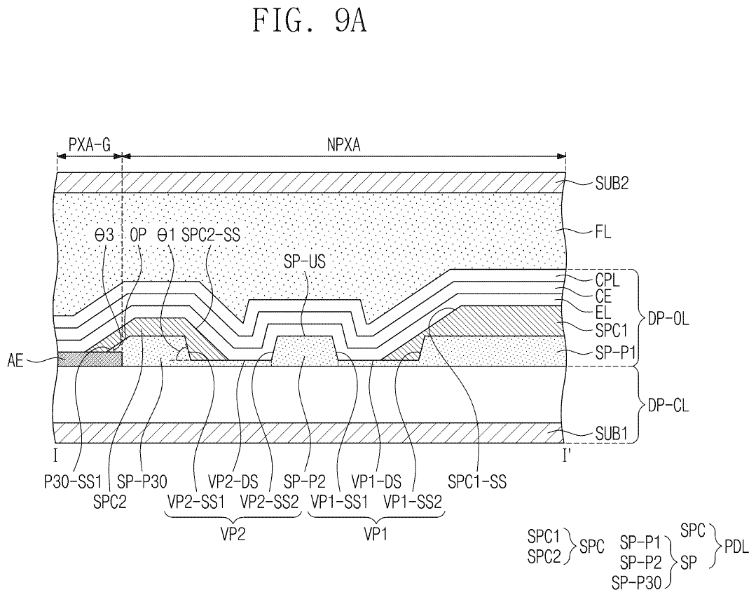

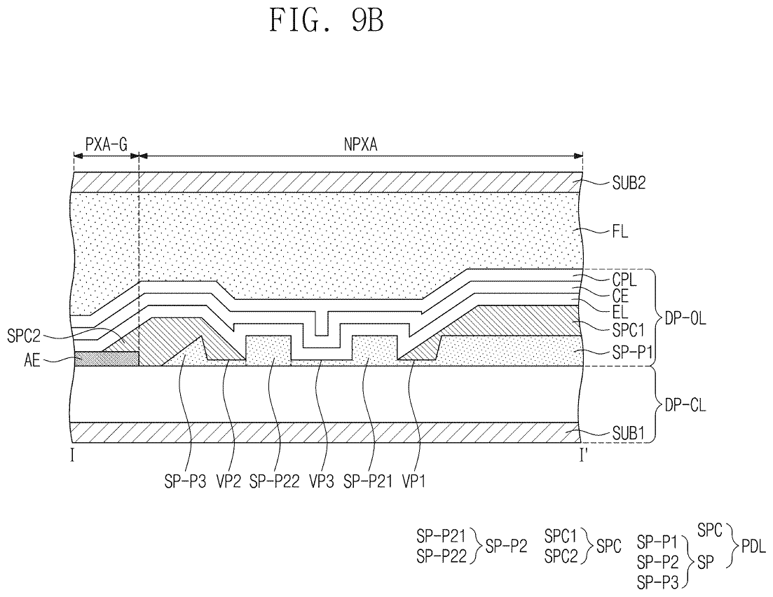

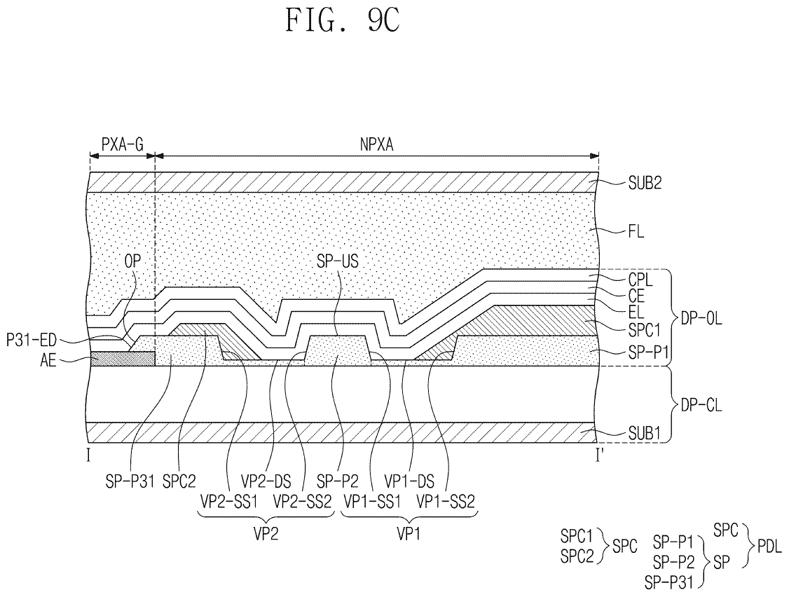

FIGS. 9A to 9C are cross-sectional views of display panels according to some example embodiments of the inventive concepts. The components described above are denoted as the same reference numerals or symbols, and detailed descriptions thereof are omitted.

As illustrated in FIG. 9A, an opening OP is defined in a third portion SP-P30 °a pixel insulating layer SP. An edge of the third portion SP-P30 defining the opening OP may overlap a first electrode AE. The third portion SP-P30 may include an inclined surface P30-SS1 overlapping the first electrode AE, and may include an inner side surface VP2-SS1 defining a second groove VP2. An inclination angle θ3 of the inclined surface P30-SS1 of the third portion SP-P30 may be smaller than an inclination angle θ1 of the inner side surface VP2-SS1. For example, the inclination angle θ3 of the inclined surface P30-SS1 of the third portion SP-P30 may be substantially equal to the inclination angle θ2 (see FIG. 8B) of the inclined surface SPC2-SS of the second spacer pattern SPC2.

Referring to FIG. 9B, a third groove VP3 having a closed line shape disposed between a first groove VP1 and a second groove VP2 may be further defined in a pixel insulating layer SP. The third groove VP3 may not overlap a first spacer pattern SPC1 and a second spacer pattern SPC2. Because the third groove VP3 is further defined, when a crack occurs at an upper surface of the first spacer pattern SPC1, flowing of a filler FL into a light-emitting region PXA-G may be further delayed.

Referring to FIG. 9C, a third portion SP-P31 of a pixel insulating layer SP may have an opening OP defined therein and overlap a second spacer pattern SPC2 and a first electrode AE. An edge P31-ED of the third portion SP-P31, which defines the opening OP, may be exposed from the second spacer pattern SPC2. The second spacer pattern SPC2 may not overlap a light-emitting region PXA-G and may form an inclined surface on an upper surface, not the edge P31-ED, of the third portion SP-P31.

A pixel-defining structure of a display panel according to some example embodiments of the inventive concepts may include a pixel insulating layer having grooves defined therein and spacer patterns disposed on the pixel insulating layer and partially overlapping the grooves. The spacer pattern may reduce or prevent a filler positioned between a first substrate and a second substrate of the display panel from being introduced into an emission layer through the groove of the pixel insulating layer. The spacer pattern of the pixel-defining structure may suppress introduction of the filler into the emission layer, and may thus reduce or prevent a dark spot defect.

Any functional blocks shown in the figures and described above may be implemented in processing circuitry such as hardware including logic circuits, a hardware/software combination such as a processor executing software, or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

In the above, description has been made with reference to some example embodiments of the inventive concepts, but those skilled or of ordinary skill in the art may understand that various modifications and changes may be made to the disclosed example embodiments insofar as such modifications and changes do not depart from the spirit and technical scope of the inventive concepts set forth in the claims to be described later.

Therefore, the technical scope of the inventive concepts is not to be limited to the contents stated in the detailed description of the specification, but should be determined by the claims.

What is claimed is:

1. A display panel comprising:
a first substrate;
a display element layer on the first substrate, the display element layer including a first electrode, an emission layer on the first electrode, a second electrode on the emission layer, and a pixel-defining structure;
a second substrate on the display element layer and opposing the first substrate; and
a filler between the first substrate and the second substrate,
wherein the pixel-defining structure includes
a pixel insulating layer including an opening corresponding to the first electrode, a first groove having a closed line shape, and a second groove having a closed line shape and surrounding the first groove in a plan view,
a first spacer pattern partially overlapping the first groove and being on the pixel insulating layer, and
a second spacer pattern partially overlapping the second groove, being closer to the first electrode than the first spacer pattern, and being on the pixel insulating layer.

2. The display panel of claim 1, wherein
the second spacer pattern comprises an inclined surface overlapping the second groove,
the pixel insulating layer comprises an inner side surface overlapping the inclined surface of the second spacer pattern and defining the second groove, and
a first inclination angle of the inner side surface of the pixel insulating layer is greater than a second inclination angle of the inclined surface of the second spacer pattern.

3. The display panel of claim 2, wherein
the first inclination angle of the inner side surface of the pixel insulating layer is about degrees to about 90 degrees, and
the second inclination angle of the inclined surface of the second spacer pattern is equal to or greater than about 15 degrees and smaller than about 45 degrees.

4. The display panel of claim 1, wherein
the pixel insulating layer comprises a first inner side surface, a second inner side surface, and a lower surface between the first inner side surface and the second inner side surface, the first inner side surface, the second inner side surface, and the lower surface defining the first groove,
the second inner side surface is farther away from the first electrode than the first inner side surface, and
the first spacer pattern covers the second inner side surface of the first groove.

5. The display panel of claim 1, wherein
the pixel insulating layer comprises a first inner side surface, a second inner side surface, and a lower surface between the first inner side surface and the second inner side surface, the first inner side surface, the second inner side surface, and the lower surface defining the second groove,
the second inner side surface is farther away from the first electrode than the first inner side surface, and
the second spacer pattern covers the first inner side surface of the second groove.

6. The display panel of claim 1, wherein
the pixel insulating layer comprises:
a first portion overlapping the first spacer pattern;
a second portion between the first groove and the second groove; and
a third portion being a remaining portion other than the first portion and the second portion, and
the second portion does not overlap the first spacer pattern and the second spacer pattern.

7. The display panel of claim 6, wherein
the opening is defined in the third portion, and an edge of the third portion defining the opening is spaced apart from the first electrode, and
at least a portion of the second spacer pattern overlaps the first electrode.

8. The display panel of claim 6, wherein the opening is defined in the third portion, and an edge of the third portion defining the opening overlaps the first electrode.

9. The display panel of claim 8, wherein
the third portion comprises an inclined surface overlapping the first electrode and an inner side surface defining the second groove, and
a third inclination angle of the inclined surface of the third portion is smaller than a fourth inclination angle of the inner side surface of the third portion.

10. The display panel of claim 1, wherein the pixel insulating layer further includes a third groove having a closed line shape and being between the first groove and the second groove.

11. The display panel of claim 10, wherein the third groove does not overlap the first spacer pattern and the second spacer pattern.

12. The display panel of claim 1, wherein
the pixel insulating layer comprises:
a first portion overlapping the first spacer pattern;
a second portion between the first groove and the second groove; and
a third portion including the opening, the third portion overlapping the second spacer pattern and the first electrode, and
an edge of the third portion defines the opening and is exposed from the second spacer pattern.

13. The display panel of claim 1, wherein a first height of the first spacer pattern is greater than a second height of the second spacer pattern.

14. The display panel of claim 1, wherein
the second spacer pattern has a closed line shape in a plan view, and
the first spacer pattern is on an inner side of the second spacer pattern in a plan view.

15. The display panel of claim 1, wherein
the display element layer further comprises a capping layer on the second electrode, and
the filler is on the capping layer.

16. An electronic device comprising:
a display panel;
a processor configured to control the display panel; and
a power module configured to supply power,
wherein the display panel includes
a first substrate,
a display element layer on the first substrate, the display element layer including a first electrode, an emission layer on the first electrode, a second electrode on the emission layer, and a pixel-defining structure,
a second substrate on the display element layer and opposing the first substrate, and
a filler between the first substrate and the second substrate, and
wherein the pixel-defining structure includes
a pixel insulating layer including an opening corresponding to the first electrode, a first groove having a closed line shape, and a second groove having a closed line shape and surrounding the first groove in a plan view,
a first spacer pattern partially overlapping the first groove and being on the pixel insulating layer, and
a second spacer pattern partially overlapping the second groove, being closer to the first electrode than the first spacer pattern, and being on the pixel insulating layer.

17. The electronic device of claim 16, wherein
the second spacer pattern comprises an inclined surface overlapping the second groove,
the pixel insulating layer comprises an inner side surface overlapping the inclined surface of the second spacer pattern and defining the second groove, and
a first inclination angle of the inner side surface of the pixel insulating layer is larger than a second inclination angle of the inclined surface of the second spacer pattern.

18. The electronic device of claim 17, wherein
the first inclination angle of the inner side surface of the pixel insulating layer is about degrees to about 90 degrees, and
the second inclination angle of the inclined surface of the second spacer pattern is equal to or greater than about 15 degrees and smaller than about 45 degrees.

19. The electronic device of claim 16, wherein
the pixel insulating layer comprises a first inner side surface, a second inner side surface, and a lower surface between the first inner side surface and the second inner side surface, the first inner side surface, the second inner side surface, and the lower surface defining the first groove,
the second inner side surface is farther away from the first electrode than the first inner side surface, and
the first spacer pattern covers the second inner side surface of the first groove.

20. The electronic device of claim 16, wherein
the pixel insulating layer comprises:
a first portion overlapping the first spacer pattern;
a second portion between the first groove and the second groove; and
a third portion being a remaining portion other than the first portion and the second portion, and
the second portion does not overlap the first spacer pattern and the second spacer pattern.
